(19) United States
(12) Patent Application Publication
(10) Pub. No.: US 2011/0085292 A1
(43) Pub. Date: Apr. 14, 2011

(54) ARRANGEMENT OF COMPUTER HOST

(76) Inventors: Chih-Hsiang Chien, Taipei (TW); Chih-Hsieh Chen, Taipei (TW)

(21) Appl. No.: 12/637,912

(22) Filed: Dec. 15, 2009

(30) Foreign Application Priority Data
Oct. 12, 2009 (TW) 098134551

(51) Int. Cl. H05K 7/00

(52) U.S. Cl. 361/679.33

(57) ABSTRACT

An arrangement of a computer host with high compatibility is disclosed. The computer host has a housing. A motherboard is disposed in right half of the housing. The motherboard is provided with an indention for accommodating a heat dissipation unit. A hard disk drive is disposed in left half of the housing. The hard disk drive substantially aligns with the heat dissipation unit. This arrangement can be applied in various computer hosts.

### BACKGROUND OF THE INVENTION

1. Technical Field

The invention generally relates to computers, and particularly to arrangement of portable computers.

2. Related Art

With advance of the semiconductor industry, computers tend to be more and more compact and light. Portable computers such as laptops are frequently weeded out by new models. Therefore, the development schedules of the portable computers are tight. The manufactures of computers must expect a motherboard which can be used in various models of productions.

Computer productions always have many models with different specification. However, for satisfying requirements of consumers, some models may equip an optical disk drive, and some models may equip double hard disk drive. The abovementioned motherboard can not provide high compatibility for various productions. And the elements on the motherboard also lack selectivity and interchangeability. Thus the development period is hard to be shortened and the cost is hard to be lowered.

### SUMMARY OF THE INVENTION

An object of the invention is to provide an arrangement of computer host with high compatibility, which can be applied in a housing and can shorten development period. Another object of the invention is to provide an arrangement of computer host with a free room which can accommodates various devices such as a wireless network device.

To accomplish the abovementioned objects, the arrangement of computer host of the invention provides a housing having a space therein. A motherboard is disposed in right half of the housing. The motherboard is provided with an indention for accommodating a heat dissipation unit. A hard disk drive is disposed in left half of the housing. The hard disk drive substantially aligns with the heat dissipation unit. This arrangement can be applied in various computer hosts.

### BRIEF DESCRIPTION OF THE DRAWINGS

FIG. 1 is a perspective view of the invention;

FIG. 2 is a planar view of the invention;

FIG. 3 is a planar view of the second embodiment of the invention;

FIG. 4 is a planar view of the third embodiment of the invention; and

FIG. 5 is a planar view of the fourth embodiment of the invention.

### DETAILED DESCRIPTION OF THE INVENTION

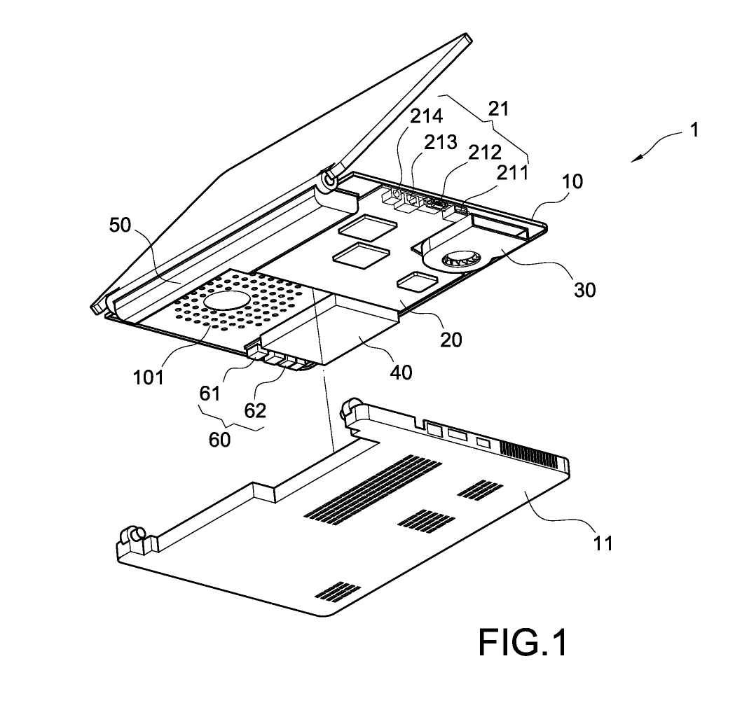

FIG. 1 is a perspective view of the computer host of the invention. The computer host of the invention is arranged in a housing 10. This figure adopts a viewing point from the bottom. The housing 10 is covered by a bottom plate 11.

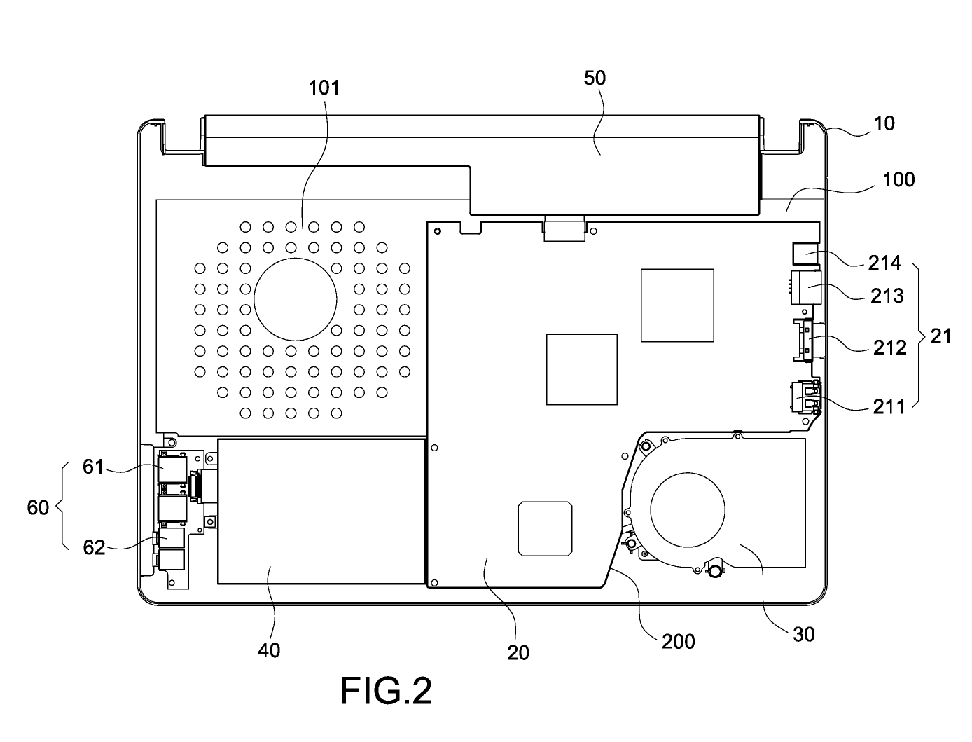

FIG. 2 is a planar view of the computer host of the invention. There are a motherboard 20, a heat dissipation unit 30 and a hard disk drive 40 in the housing.

The housing 10 has a space 100 therein. The motherboard 20 is disposed in right half of the space 100. The motherboard 20 is provided with a CPU, memory module and chipset. An I/O module 21 is disposed at the right edge of the motherboard 20. The I/O module 21 includes a USB connector 211, a D-sub connector 212, a RJ45 connector 213 and a power jack 214. Additionally, the right front of the motherboard 20 is provided with an indention 200. A connection port 60 is disposed at the left of the space 100. The connection port 60 includes a plurality of USB connectors 61 and phone jacks 62.

The heat dissipation unit 30 is disposed in the indention 200. In this embodiment, the heat dissipation unit 200 is a fan. The hard disk drive 40, such as a 2.5 inch SATA hard disk drive, is disposed in left half of the space 100. And the hard disk drive substantially aligns with the heat dissipation unit 30. A battery module 50 is disposed at a portion of the space 100 far from the indention 200. And a free room 101 is formed between the left of the motherboard 20 and the rear of the hard disk drive 40. In other words, the free room 101 is enclosed by the battery module 50, hard disk drive 40 and motherboard 20. The free room 101 can be used to accommodate various devices.

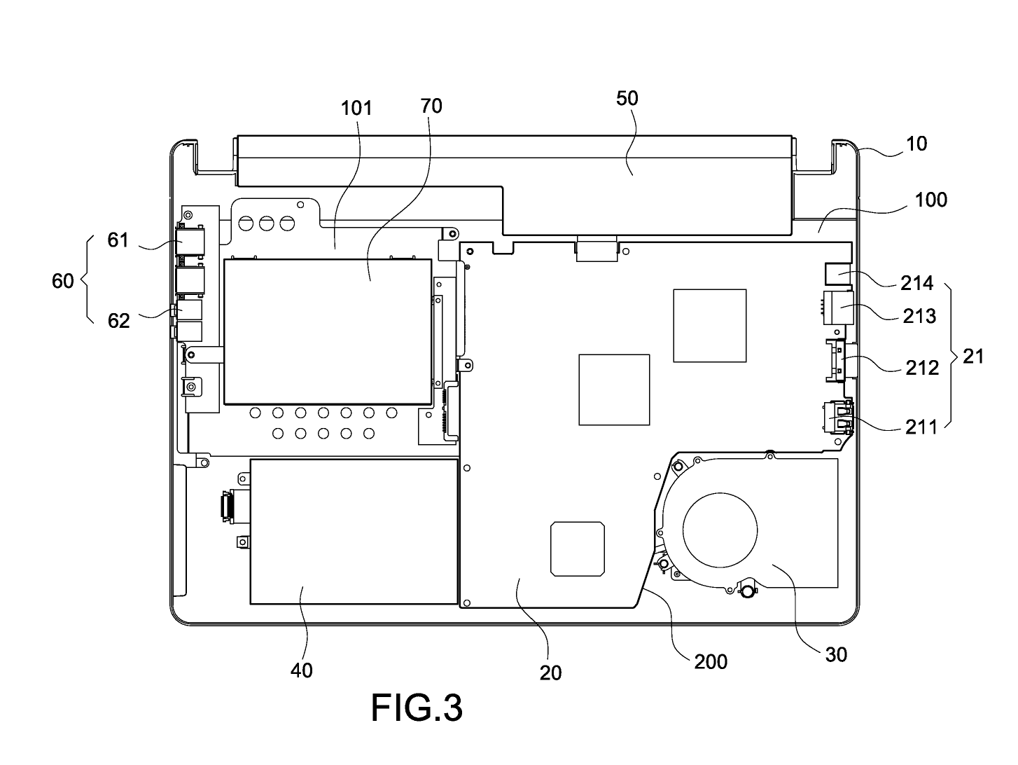

FIG. 3 shows the second embodiment of the invention. This embodiment is roughly the same as the abovementioned first embodiment. The difference between these two embodiments is that there is another hard disk drive 70 disposed in the free room 101.

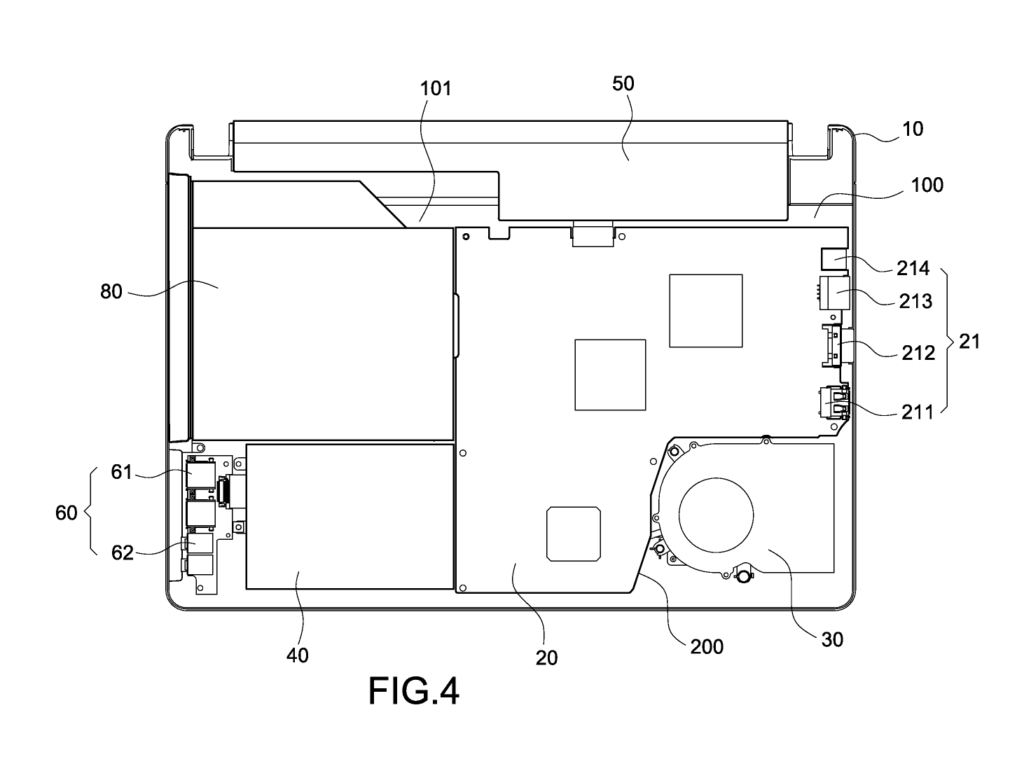

FIG. 4 shows the third embodiment of the invention. In this embodiment, an optical disk drive 80 is disposed in the free room 101.

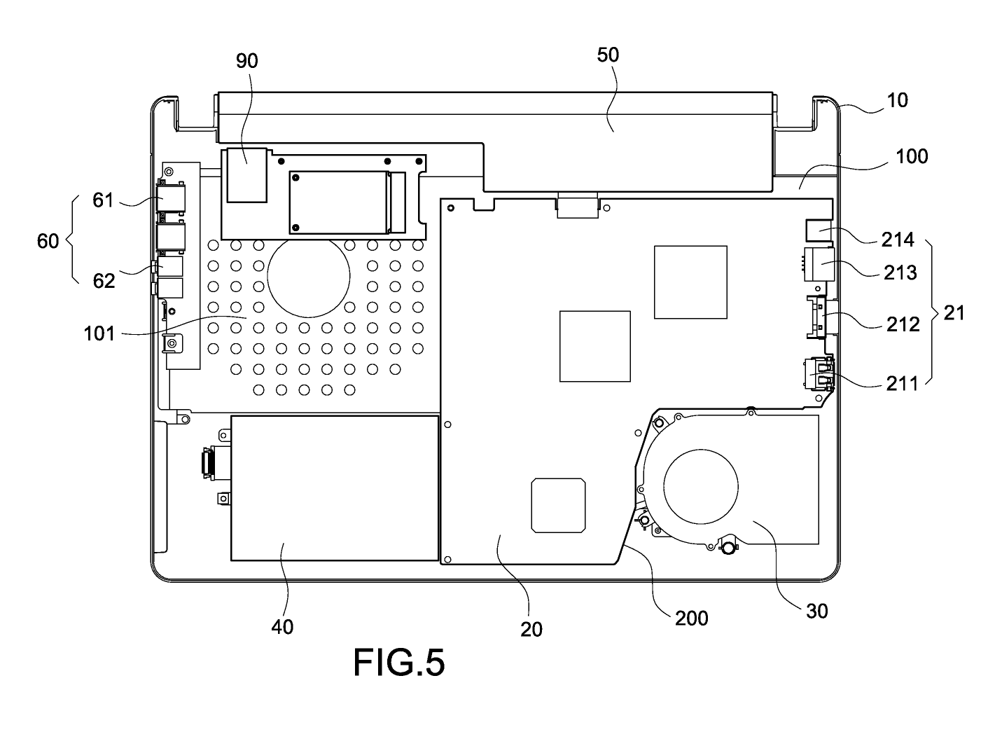

FIG. 5 shows the fourth embodiment of the invention. A wireless network module 90 is disposed in the free room 101.

Embodiments of the invention have been described. Nevertheless, it will be understood that various modifications may be made without departing from the spirit and scope of the invention. Accordingly, other embodiments are the scope of the following claims.

What is claimed is:

1. An arrangement of a computer host, comprising:
a housing having a space therein;
a motherboard disposed at a substantially right half of the space and having an indention at a right corner thereof;
a heat dissipation unit disposed in the indention; and
a hard disk drive disposed at a left portion of the space and aligned with the heat dissipation unit.

2. The arrangement of a computer host of claim 1, further comprising an I/O module disposed at a right side of the motherboard.

3. The arrangement of a computer host of claim 2, wherein the I/O module comprises a USB connector, a D-sub connector, a RJ45 connector and a power jack.

4. The arrangement of a computer host of claim 1, further comprising a connection port at a left portion of the space.

5. The arrangement of a computer host of claim 1, further comprising a free room formed between the left of the motherboard and the rear of the hard disk drive.

6. The arrangement of a computer host of claim 5, further comprising an another hard disk drive disposed in the free room.

7. The arrangement of a computer host of claim 5, further comprising an optical disk drive disposed in the free room.

8. The arrangement of a computer host of claim 5, further comprising a wireless network module disposed in the free room.

9. The arrangement of a computer host of claim 1, wherein the heat dissipation unit is a fan.

10. The arrangement of a computer host of claim 1, wherein the hard disk drive is a 2.5 inch SATA hard disk drive.

11. An arrangement of a computer host, comprising:
a housing having a space therein;
a motherboard disposed at a substantially right half of the space and having an indention at a right corner thereof;
a heat dissipation unit disposed in the indention;
a hard disk drive disposed at a left portion of the space and aligned with the heat dissipation unit; and
a battery module disposed on one side of the motherboard far from the indention, wherein a free room is formed among the battery module, the hard disk drive and the motherboard.

12. The arrangement of a computer host of claim 11, further comprising an I/O module disposed at a right side of the motherboard.

13. The arrangement of a computer host of claim 12, wherein the I/O module comprises a USB connector, a D-sub connector, a RJ45 connector and a power jack.

14. The arrangement of a computer host of claim 11, further comprising a connection port at a left portion of the space.

15. The arrangement of a computer host of claim 11, further comprising an another hard disk drive disposed in the free room.

16. The arrangement of a computer host of claim 11, further comprising an optical disk drive disposed in the free room.

17. The arrangement of a computer host of claim 11, further comprising a wireless network module disposed in the free room.

18. The arrangement of a computer host of claim 11, wherein the heat dissipation unit is a fan.

19. The arrangement of a computer host of claim 11, wherein the hard disk drive is a 2.5 inch SATA hard disk drive.
